(19) United States
(12) Patent Application Publication
(10) Pub. No.: US 2006/0246695 A1
(43) Pub. Date: Nov. 2, 2006

(54) Flip chip method

(76) Inventors: Young-Jae Kim, Suwon-si (KR); Soon-Young Kim, Yongin-si (KR)

Correspondence Address: STANZIONE & KIM, LLP, 919 18TH STREET, N.W., SUITE 440, WASHINGTON, DC, 20006, US

(21) Appl. No.: 11/340,657

(22) Filed: Jan. 27, 2006

(30) Foreign Application Priority Data
Apr. 19, 2005 (KR) 2005-32155

(51) Int. Cl. H01L 21/20

(52) U.S. Cl. 438/584

(57) ABSTRACT

A flip chip method using gold bumps and inkjet printing is disclosed. The flip chip method, comprising: forming gold bumps on a semiconductor chip, printing solder ink on a first pad of a substrate using inkjet printing, mounting the semiconductor chip on the substrate so that the gold bump and the first pad are in contact, and reflowing the substrate, can reduce process costs and process times, can mount semiconductor chips with microscopic pitch onto a substrate, and can implement substrate pads with microscopic pitch, by eliminating the need to form solder resist.

### CROSS-REFERENCE TO RELATED APPLICATIONS

This application claims the benefit of Korean Patent Application No. 2005-32155 filed with the Korea Industrial Property Office on Apr. 19, 2005, the disclosure of which is incorporated herein by reference.

### BACKGROUND OF THE INVENTION

1. Field of the Invention

The present invention relates to a flip chip method, and in particular to a flip chip method of attaching gold bumps formed on a semiconductor chip to a pad of a substrate using solder ink printed by inkjet printing.

2. Description of the Related Art

Fastening or physically connecting a chip to a substrate is called bonding, and several methods of bonding exist, such as die bonding, wire bonding, and flip chip bonding, etc. Here, flip chip bonding is a procedure of forming bumps on a connection pad of a chip and directly connecting to a PCB substrate. Because it does not require prior connection processes and is a simple and modest procedure, while providing superior results in terms of degree of integration and performance, it is attracting much attention in electronic products trending towards ever smaller devices.

Today, the flip chip method is used in various applications, including internet backbone switching. Using the flip chip method can improve the electrical and thermal performance of a switching system and can minimize not only the net wiring length, but also the substrate and overall system itself. The flip chip method is used today in computers and mobile phones in response to needs involving size, mass, and minimum wiring width.

Examples of conventional flip chip methods, as illustrated in FIGS. 1 to 3, include methods using solder bumps, methods of rearranging solder bumps, and methods using gold bumps and adhesive.

FIG. 1 is a cross sectional view illustrating a conventional flip chip method using solder bumps 13, where the solder bumps 13 are melted while in contact with substrate pads 19 to connect a semiconductor chip 11 to the substrate pads 19. Cream solder 15 is coated on the number of substrate pads 19 formed on the substrate 17 for adhesion to the solder bumps 13. The cream solder 15 is coated on the substrate pads 19 by screen printing using a metal mask. Also, solder resist 21 is formed between the substrate pads 19 to prevent short-circuiting between substrate pads due to the running of molten solder bumps 13.

However, with the recent trend of continuous increase in degree of integration and decrease in size of semiconductor chips, not only is the number of chip pads electrically connected to a substrate pad increasing, but also the pitch of the chip pads is decreasing, and consequently the size and pitch (gap) of substrate pads are also becoming microscopic. Therefore, the openings of the metal mask printing solder cream onto the substrate pad 19 are also becoming microscopic, which hinders the discharge of solder cream passing through the openings of the metal mask. Further, since the solder resist 21 must be considered also in the design of the substrate, a restraint is imposed in the design of a substrate pad having microscopic pitch.

FIG. 2 is a schematic diagram illustrating a conventional flip chip method that rearranges the solder bumps 13 to solve the above problems. This method rearranges the pads by connecting patterns 27 again from the original chip pads 25 of a semiconductor chip shown in FIG. 2, and then forming solder bumps 13 on top of them. However, this method creates the problem of increasing process times and process costs.

FIG. 3 is a cross sectional view illustrating a conventional flip chip method using gold bumps 14 and adhesive 11. As shown in FIG. 3, gold bumps 14 are formed on the semiconductor chip 11 in correspondence to the substrate pads 19. An adhesive is coated on a surface of the substrate 17, such as an anisotropic conductive film (ACF) or non-conductive paste (NCP). The gold bumps 14 are joined to the substrate pads 19 by heat compression.

Thus, with the conventional flip chip method using gold bumps and adhesive, the high costs of the adhesives such as anisotropic conductive films (ACF) or non-conductive paste (NCP) and the use of bonding methods such as heat compression via a flip chip bonder result in prolonged process times and increased process costs.

### SUMMARY OF THE INVENTION

The present invention has been developed to solve the foregoing problems, and it is therefore an object of the invention to provide a flip chip method which can not only reduce process costs and process times, but can also mount semiconductor chips with microscopic pitch onto a substrate.

Another object of the invention is to provide a flip chip method that can reduce the pitch between substrate pads by eliminating the need to form solder resist.

Additional aspects and advantages of the present general inventive concept will be set forth in part in the description which follows and, in part, will be obvious from the description, or may be learned by practice of the general inventive concept.

To achieve the above objectives, the present invention is realized in the following embodiments.

A flip chip method according to an embodiment of the invention comprises: forming gold bumps on a semiconductor chip, printing solder ink on a first pad of a substrate using inkjet printing, mounting the semiconductor chip on the substrate so that the gold bumps and the first pad are in contact, and reflowing the substrate.

The flip chip method of the present invention may further comprise: printing cream solder on a second pad of the substrate through screen printing, and mounting a general component on the second pad. Also, the flip chip method according to an embodiment of the invention may further comprise underfilling.

Preferably, the gold bumps are formed by plating, and the semiconductor chip and the general component are mounted on the substrate using a chip mounter to increase process speed.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross sectional view illustrating a conventional flip chip method using solder bumps.

FIG. 2 is a schematic diagram illustrating a conventional flip chip method using a rearrangement of solder bumps.

FIG. 3 is a cross sectional view illustrating a conventional flip chip method using gold bumps and adhesive.

FIG. 4 is a flowchart illustrating a flip chip method according to an embodiment of the present invention.

FIG. 5a is a cross sectional view illustrating gold bumps formed on a semiconductor chip.

FIG. 5b is a plan view illustrating gold bumps formed on a semiconductor chip.

FIG. 6 is a plan view illustrating second pads coated with cream solder, on which general components are mounted by screen printing using a metal mask.

FIG. 7 is a plan view illustrating first pads of a substrate with solder ink printed using inkjet printing.

FIG. 8 is a cross sectional view illustrating solder ink formed on first pads of a substrate by inkjet printing.

FIG. 9 is a schematic diagram illustrating the mounting of a semiconductor chip and general components using a chip mounter.

FIG. 10 is a cross sectional view illustrating gold bumps and first pads of substrates joined as solder ink is melted.

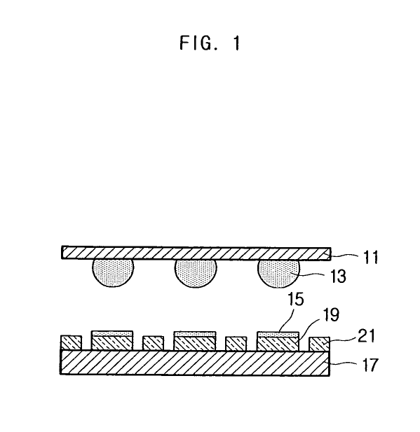

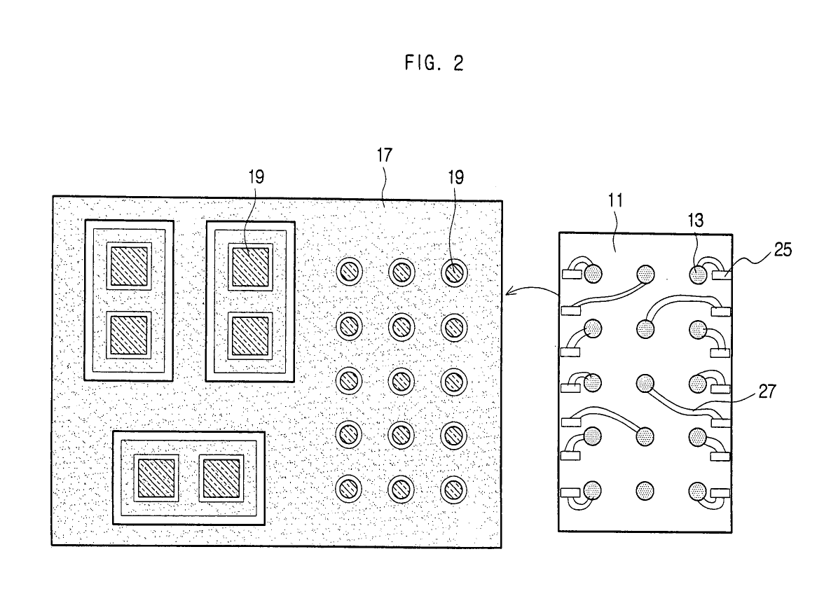

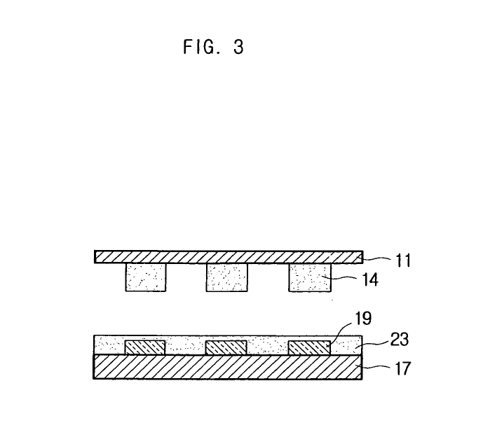

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

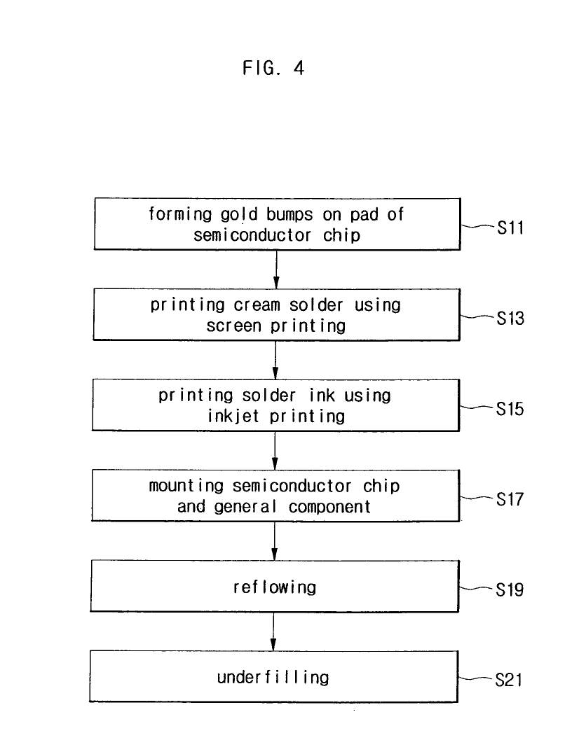

FIG. 4 is a flowchart illustrating a flip chip method according to an embodiment of the present invention. As shown in FIG. 4, a flip chip method of the present invention comprises: forming gold bumps on a semiconductor chip (S11), printing cream solder on a second pad of the substrate through screen printing (S13), printing solder ink on a first pad of a substrate using inkjet printing (S15), mounting semiconductor chips and general components (S17), reflowing (S19), and underfilling (S21).

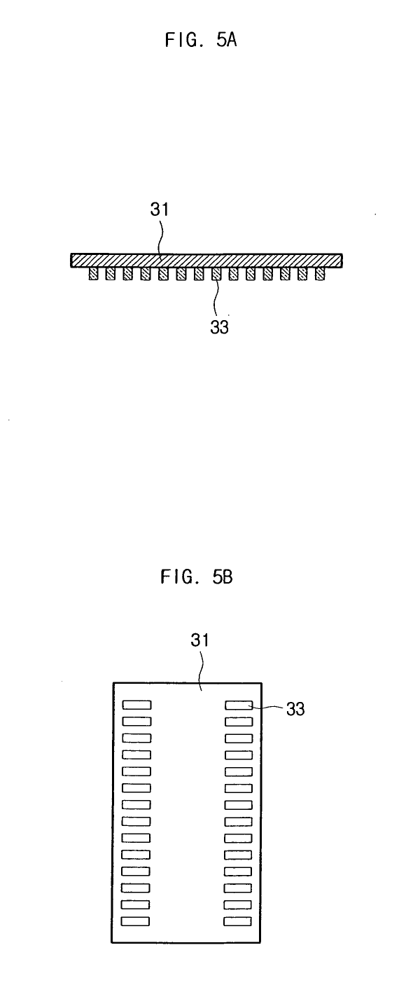

FIGS. 5a and 5b are a cross sectional view and a plan view illustrating forming gold bumps 33 on a semiconductor chip 31 (S11). Gold (Au) has the advantage of being a ductile metal and an excellent conductor of electricity, as well as having superior thermal reliability and appearance. The gold bumps 33 are formed on the semiconductor chip 31 by plating. The width and height of the gold bumps 33 and the pitch between the gold bumps 33 may vary depending on the pads (not shown) of the substrate. When the semiconductor chip 31 is mounted on a substrate, the gold bumps 33 are joined with the first pads by the solder ink printed on the first pads.

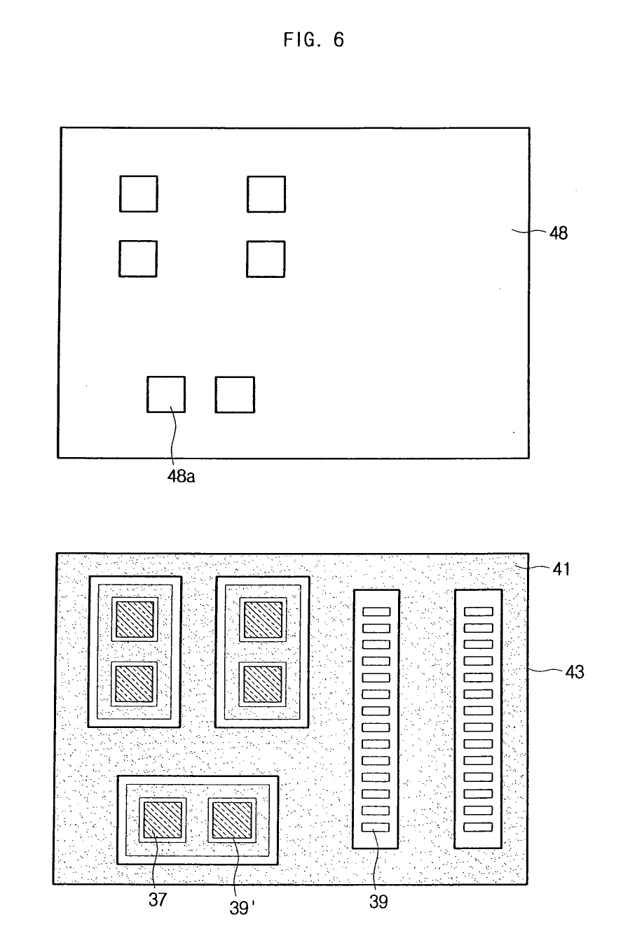

FIG. 6 is a plan view illustrating coating cream solder 37 onto the second pads 39′ of the substrate 43 using a metal mask 48 (S13). As shown in FIG. 6, first pads 39, having a microscopic pitch and on which semiconductor chips are mounted, and second pads 39′, having a relatively larger pitch and on which general components (resistance, capacitors, inductors, OP amps, etc.) are mounted, are formed on the substrate 43. Since the discharge of cream solder is better for the second pads 39′ compared to the first pads 39, as the size of the pads themselves and the pitch (gap) between pads are greater, the cream solder 37 may easily be coated on the second pads 39′ using a metal mask 48. A number of holes 48a having the same shapes as the second pads 39′ are formed on the metal mask 48. Solder resist 41 (illustrated gray in the figure) is coated between the second pads 39′.

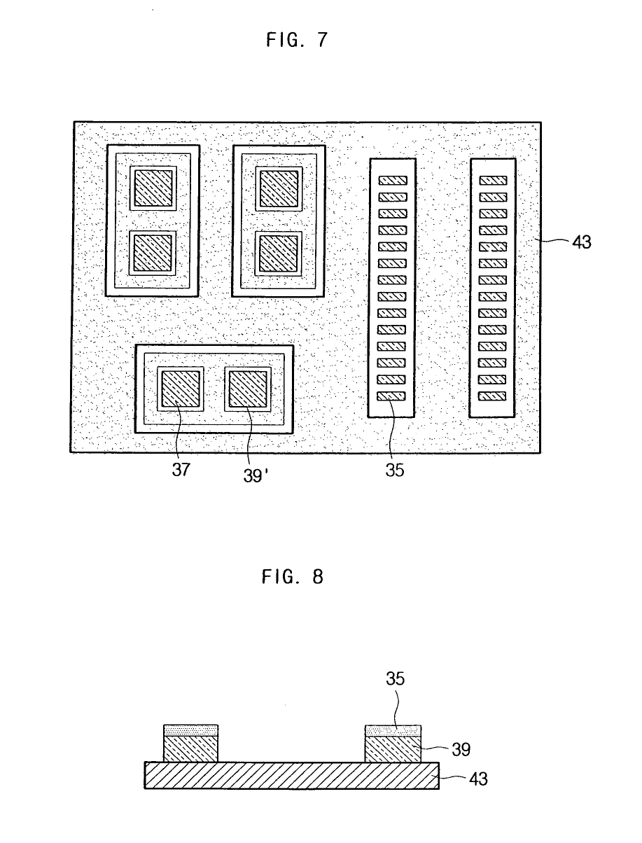

FIG. 7 is a plan view illustrating printing solder ink on the first pads 39 of the substrate 43 using inkjet printing (S15), and FIG. 8 is a cross sectional view illustrating solder ink formed on the first pads 39 of the substrate 43 by inkjet printing.

According to FIG. 7, since the first pads 39 on which a semiconductor chip (not shown) is mounted has microscopic pitch, it is difficult to utilize screen printing using cream solder and a metal mask as described above. Thus, an inkjet printer is used, which not only allows the printing of microscopic patterns but also reduces operation time, to print solder ink 35 on the first pads 39. As shown in FIG. 8, the solder ink 35 is printed so that its thickness is lower than the thickness of the gold bumps 33. The thickness of the solder ink 35 may vary depending on the size and pitch of the gold bumps 33.

Solder resist 41 is not coated on the first pad 39 portions of the substrate 43. This is because the gold bumps 33 attached to the first pads 39 do not melt and flow towards other pads, as do conventional solder bumps. Also, the solder ink 35 does not flow towards other pads either, because it is printed to be very thin. Thus, with the first pads 39 according to an embodiment of the invention, the gap between pads may be made to be microscopic, since there is no need for solder resist. Moreover, it is also possible to mount semiconductor chips having microscopic pitch.

The solder ink 35 is ink in the form of microscopic droplets containing metal nanoparticles. The metals contained in the solder ink 35 include tin (Sn) 63 mass % and lead (Pb) 37 mass %. Silver may be included to increase the conductivity of the lead, so that tin (Sn) 62 mass %, lead (Pb) 36 mass %, and silver (Ag) 2 mass % may be used. Also, lead, which is toxic to the human body, may be excluded, so that lead-free solder ink 35 may be used containing tin (Sn), silver (Ag), and copper (Cu). The solder ink 35 is melted during reflowing (S19) and forms an intermetallic compound (IMC) between the gold bumps 33 and the first pads 39. Since an intermetallic compound is a very stable material, it has a high reliability with regard to adhesion. Plus, since the solder ink 35 acts as the adhesive (NCP, ACF) in prior art, the flip chip method of the present invention does not require an expensive adhesive, so that the process costs may be reduced.

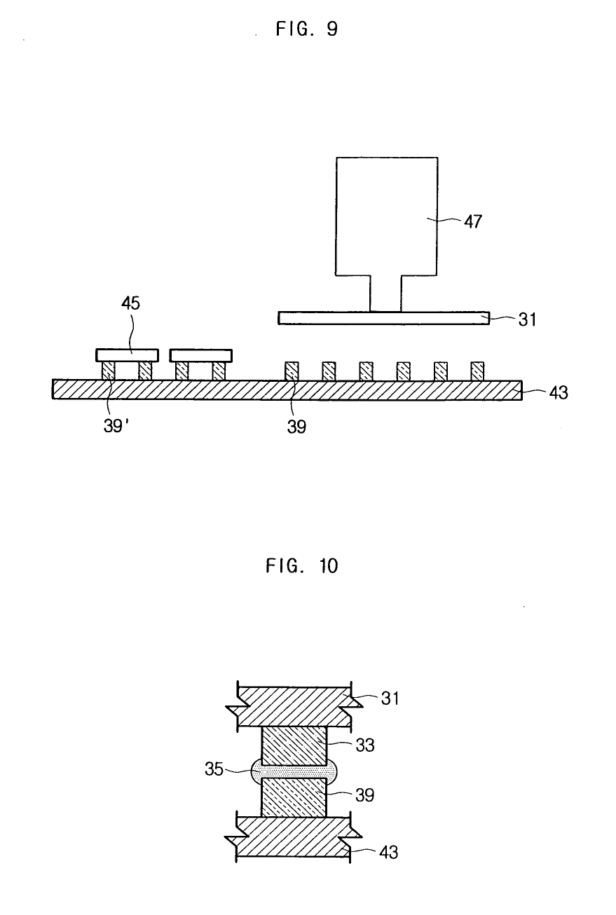

FIG. 9 is a schematic diagram illustrating mounting semiconductor chips 31 and general components 45 using a chip mounter 47 (S17).

As shown in FIG. 9, the chip mounter 47 mounts semiconductor chips 31 on the first pads 39 and mounts general components 45 such as resistance, capacitors, inductors, OP amps, etc., on the second pads 39′. Since the semiconductor chip 31 and the general components 45 are mounted by a typical chip mounter 47 at high speeds, and since there are no procedures involving a flip chip bonder, the flip chip method of the present invention can reduce process times.

The chip mounter 47 is a device which mounts semiconductor chips or general components at high speeds onto a pad of a substrate on which cream solder 37 or solder ink 35 is formed. The chip mounter 47 can not only mount small chips such as 2125, 3216, and TANTAL, it can also mount IC's such as connector types, small outline packages (SOP: IC's in which the leads face outward in either direction), small outline junctions (SOJ: IC's in which the leads face inward in either direction), quad flat packages (QFP: flat square IC's in which the leads face outward), plastic leaded chip carriers (PLCC: IC's in which the leads face inward), ball grid arrays (BGA: leadless components in which balls of solder are attached to the bottom of the packages in grid arrays), and chip size packages (CSP), etc., at high speeds.

FIG. 10 is a cross sectional view illustrating the formation of an intermetallic compound between the gold bumps 33 and the first pads 39 as the solder ink 35 is melted by the reflowing (S19) according to an embodiment of the invention. Reflowing refers to the procedure of melting the cream solder 37 and the solder ink 35 by heating the substrate 43, on which the semiconductor chips 31 and general components 45 are mounted, to a certain temperature. The reflow temperature varies depending on the cream solder 37 and solder ink 35 used, but is generally about 200° C. The reflow time also varies depending on the size of the substrate and the number or type of the chips. In typical reflowing, it is preferable that the temperature be slowly increased and slowly decreased to prevent the running of the cream solder and the occurrence of cracks.

The gold bumps 33 and the first pads 39 are attached via the intermetallic compound formed from the solder ink 35, and since the solder ink 35 has a very thin thickness of 30 μm or less, it does not run even after melting.

The underfilling (S21) is for completely filling the bottom of the semiconductor chips 31 or general components 45 using insulator resin. Underfilling may provide a resistance to physical impacts, such as impacts from falls or displacement impacts of the substrate. It may also prevent malfunctioning caused by thermal shocks due to changes in operational temperature, electric migration due to dust or humidity, or α-rays from lead. Preferably, the resin used for underfilling should not only be physically and chemically stable, it should also show rapid infiltration at high temperatures. In addition, bubbles must not form within the syringe. Devices with which constant coating and rapid filling of the resin are possible are preferable for the underfilling devices. After filling the resin using the underfilling device, the resin is stiffened using a stiffening device.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

According to the present invention comprised as set forth above, the invention can not only can reduce process costs and process times, it can mount semiconductor chips with microscopic pitch onto a substrate.

In addition, the invention can implement substrate pads with microscopic pitch, by eliminating the need to form solder resist.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A flip chip method comprising:
forming gold bumps on a semiconductor chip;
printing solder ink on a first pad of a substrate using inkjet printing;
mounting the semiconductor chip on the substrate so that the gold bumps and the first pad are in contact; and
reflowing the substrate.

2. The method of claim 1, further comprising:
printing cream solder on a second pad of the substrate through screen printing; and
mounting a general component on the second pad on which is printed the cream solder.

3. The method of claim 1, further comprising underfilling.

4. The method of claim 2, further comprising underfilling.

5. The method of claim 1, wherein the gold bumps are formed by plating.

6. The method of claim 2, wherein the gold bumps are formed by plating.

7. The method of claim 2, wherein the semiconductor chip and the general component are mounted by a chip mounter.
